(19) United States
(12) Patent Application Publication
(10) Pub. No.: US 2017/0198385 A1
(43) Pub. Date: Jul. 13, 2017

(54) COATING LAYER STRUCTURE APPLIED TO MACHINE ELEMENT AND MANUFACTURING METHOD THEREOF

(71) Applicants: FUSHENG INDUSTRIAL CO.,LTD., Taipei City (TW); H & H-T CO., LTD., Taipei City (TW)

(72) Inventors: YI-CHAO HUANG, NEW TAIPEI CITY (TW); CHUAN-LING HU, Taipei City (TW)

(21) Appl. No.: 15/177,309

(22) Filed: Jun. 8, 2016

(30) Foreign Application Priority Data
Jan. 13, 2016 (TW) 105100916

(51) Int. Cl. C23C 14/06; C01B 31/04; C23C 14/34

(52) U.S. Cl. CPC C23C 14/0688; C23C 14/34; C01B 31/0446

(57) ABSTRACT

A manufacturing method a coating layer structure applied to a machine element includes: forming a continuous graphene structure layer on a metal substrate; and forming a coating layer on the continuous graphene structure layer for cooperatively protecting the metal substrate. The continuous graphene structure layer is disposed between the metal substrate and the coating layer to act as a buffer structure between the metal substrate and the coating layer.

### BACKGROUND OF THE INVENTION

1. Field of the Invention

The instant disclosure relates to a coating layer structure and manufacturing method thereof; in particular, to a coating layer structure applied to a machine element and manufacturing method thereof.

2. Description of Related Art

A fluid machine, also known as turbo machinery, is a generic term of a large class of mechanical products which use a fluid as a working medium, such as pumps, fans and air compressors. The air compressor is used to compress air for increasing gas pressure. The air compressor is divided into oil air compressors and non-oil air compressors according to a requirement of lubricating oil used in a compression process. The non-oil air compressor is further divided into water jet type air compressor and dry type air compressor. Nowadays, in food, medical, and biotechnology industries, the demand of high air quality is necessary. If the air is compressed using the oil air compressor, the compressed air might contain oil. The oil is not allowed in the compressed air, and even if the oil can be removed by the subsequent processing equipment, there is still a risk of contamination to the products. Compared to the oil air compressor, the cylinder of a non-oil air compressor is a dry type, and it is not necessary to use the lubricating oil in the compression process, so as to compress air that does not contain oil and provide high quality compressed air. However, in the compression process, the heat generated from the non-oil air compressor is dissipated by a water jacket or an oil jacket outside the chassis. There is no other way to dissipate the heat generated from the non-oil air compressor, thus high operating temperature is a stringent test for the non-oil air compressor. Meanwhile, when in shutdown, condensate water would be generated in the cylinder due to decreasing temperature, and it is liable to corrode the metal of the cylinder and shorten the lifetime of the cylinder. Hence, a protecting layer is usually coated outside the metal of the cylinder and compression element (e.g., rotary piston) to elongate the lifetime of the machine.

In the non-oil air compressor, the protecting layer being used to protect the metal substrate in the air compressor is called the coating layer. The main material of the coating layer of the non-oil air compressor is engineering plastics, and polytetrafluoroethene (PTFE) is most common therein. The melting point of PTFE is 327° C., but it deteriorates above 260° C. However, the operating temperature of non-oil air compressor is usually high (between 150 to 250° C.). At such temperature, a bonding force between PTFE and the metal material and an interference load capacity generated during operation are easily decreased due to the high temperature, and the PTFE coating layer is liable to be peeled off from the metal material. When the PTFE coating layer is peeled off from the metal substrate, the metal substrate lacks the protection provided by the coating layer, and the metal material is easily attrited due to high temperature generated during operation, or is easily corroded due to condensate water generated from decreased temperature. Even, when corrosive gas is applied, it would cause the metal material getting corrosion. Therefore, how to improve the coating layer of the non-oil air compressor to obtain a superior anti-wear capability and load capacity between the coating layer and the metal substrate is one of the problems in the field.

### SUMMARY OF THE INVENTION

In view of the above, this instant disclosure provides a coating layer structure applied to a machine element and manufacturing method thereof. Via formation of a continuous graphene structure layer between a metal substrate and a coating layer of a fluid machine (e.g., air compressor), an anti-wear capability between the continuous graphene structure layer and the metal substrate and the coating layer can be increased, and a load capacity of coating layer is enhanced, such that the coating layer is not easily peeled off and the lifetime of the coating layer can be lengthened.

In order to overcome the abovementioned technical problem, one embodiment of this instant disclosure provides a manufacturing method of a coating layer structure applied to a machine element which includes: forming a continuous graphene structure layer on a metal substrate; and forming a coating layer on the continuous graphene structure layer for cooperatively protecting the metal substrate. The continuous graphene structure layer is disposed between the metal substrate and the coating layer to act as a buffer structure between the metal substrate and the coating layer.

Preferably, steps of forming the continuous graphene structure layer on the metal substrate include: depositing a mixed layer containing a carbon material and a metal material on the metal substrate; cooperatively annealing the metal substrate and the mixed layer; and separating out the carbon material from the mixed layer to form the continuous graphene structure layer.

Another embodiment of this instant disclosure provides a coating layer structure applied to a machine element which includes a continuous graphene structure layer and a coating layer. The continuous graphene structure layer is disposed on a metal substrate. The coating layer is disposed on the continuous graphene structure layer for cooperatively protecting the metal substrate. The continuous graphene structure layer is disposed between the metal substrate and the coating layer to act as a buffer structure between the metal substrate and the coating layer.

This instant disclosure has advantages in that, a coating layer structure applied to a machine element and manufacturing method thereof provided from an embodiment of this instant disclosure can increase an anti-wear capability between the continuous graphene structure layer and the metal substrate and the coating layer, and enhance a load capacity of coating layer, such that the coating layer is not easily peeled off and the lifetime of coating layer can be lengthened, since the continuous graphene structure layer formed between the metal substrate and the coating layer of the fluid machine can be used as a buffer structure between the metal substrate and the coating layer. Therefore, the coating layer structure of this instant disclosure can protect the metal substrate of the machine element to avoid any suffering of mechanical wear or corrosion caused by wetness, so as to further lengthen the lifetime of the machine element.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 shows a flow chart of a manufacturing method of a coating layer structure applied to a machine element of an embodiment in this instant disclosure;

FIG. 2 shows a flow chart of forming a continuous graphene structure layer on a metal substrate in a manufacturing method of a coating layer structure applied to a machine element of an embodiment in this instant disclosure;

FIG. 3 shows a schematic structural view of a coating layer structure applied to a machine element of an embodiment in this instant disclosure;

FIG. 4 shows a critical load test result of a coating layer formed from polytetrafluoroethylene;

FIG. 5 shows a critical load test result of a coating layer composed of polytetrafluoroethylene and molybdenum disulfide; and

FIG. 6 shows a critical load test result of a coating layer structure applied to a machine element of an embodiment in this instant disclosure.

### DETAILED DESCRIPTION OF THE PREFERRED EMBODIMENTS

Embodiments disclosed in the instant disclosure, a coating layer structure applied to a machine element and manufacturing method thereof, are illustrated via specific examples as follows, and people familiar in the art may easily understand the advantages and efficacies of the instant disclosure by disclosure of the specification. The instant disclosure may be implemented or applied by other different specific examples, and each of the details in the specification may be applied based on different views and may be modified and changed under the existence of the spirit of the instant disclosure. The figures in the instant disclosure are only for brief description, but they are not depicted according to actual size and do not reflect the actual size of the relevant structure. The following embodiments further illustrate related technologies of the instant disclosure in detail, but the scope of the instant disclosure is not limited herein.

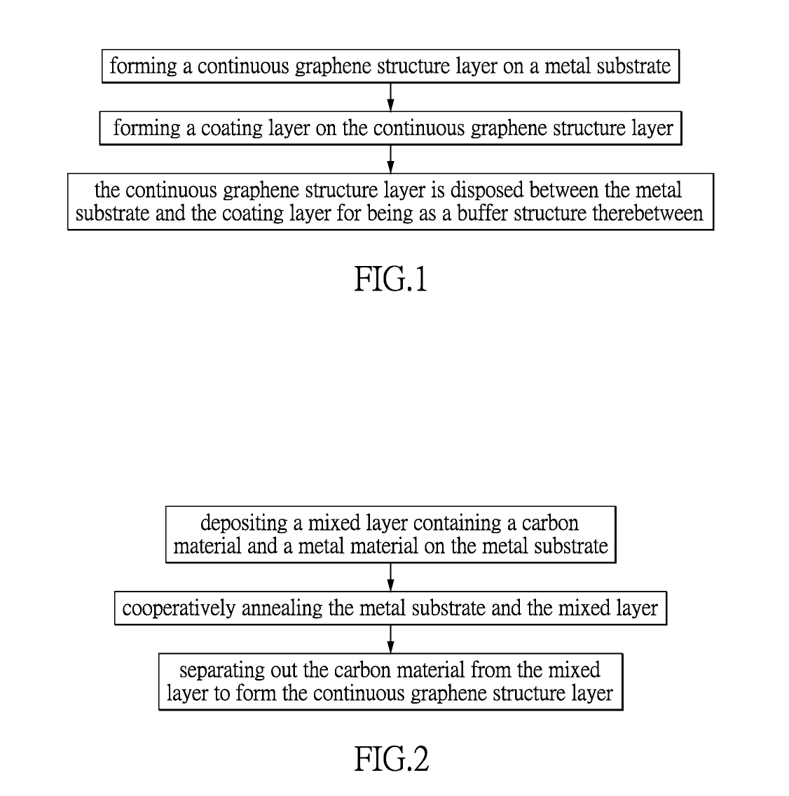

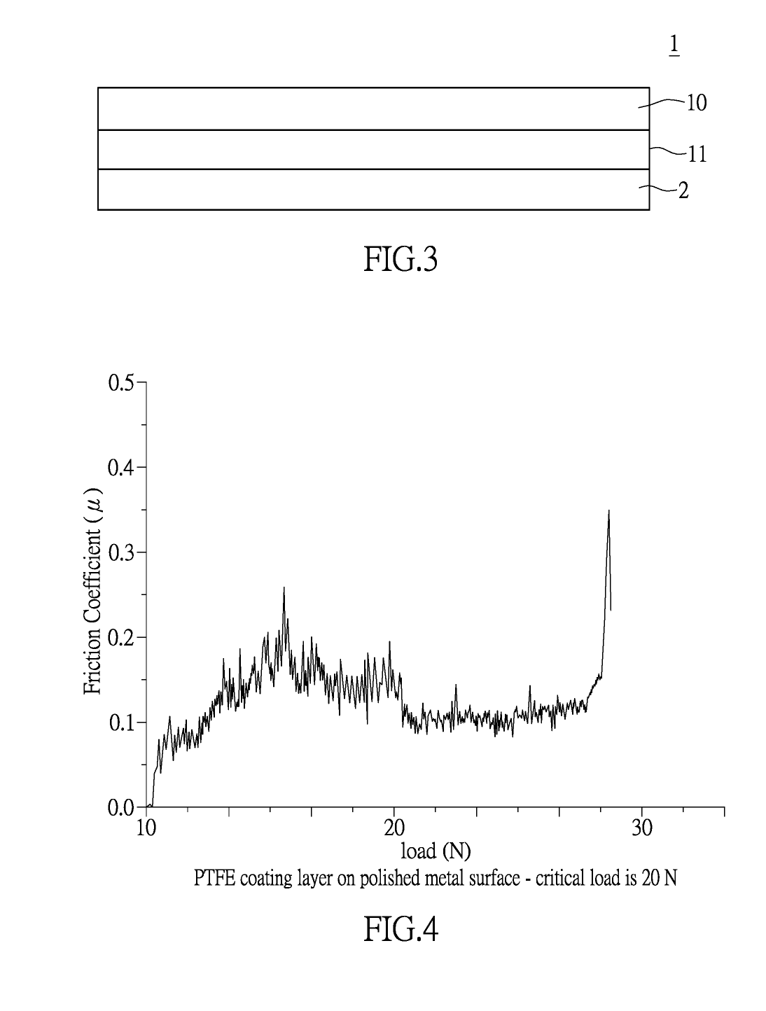

Please refer to FIGS. 1 to 3. FIG. 1 shows a flow chart of a manufacturing method of a coating layer structure applied to a machine element of an embodiment in this instant disclosure, FIG. 2 shows a flow chart of forming a continuous graphene structure layer on a metal substrate in a manufacturing method of a coating layer structure applied to a machine element of an embodiment in this instant disclosure, and FIG. 3 shows a schematic structural view of a coating layer structure applied to a machine element of an embodiment in this instant disclosure.

As shown in FIG. 1, an embodiment of this instant disclosure provides a manufacturing method of a coating layer structure 1 applied to a machine element which includes: forming a continuous graphene structure layer 11 on a metal substrate 2; and forming a coating layer 10 on the continuous graphene structure layer 11 for cooperatively protecting the metal substrate 2. The continuous graphene structure layer 11 is disposed between the metal substrate 2 and the coating layer 10 to act as a buffer structure between the metal substrate 2 and the coating layer 10.

As shown in FIG. 2, steps of forming the continuous graphene structure layer 11 on the metal substrate 2 include: a sputtering method or a vapor deposition method being used to deposit a mixed layer containing a carbon material and a metal material on the metal substrate 2, wherein the metal material in the mixed layer is nickel or nickel alloy; cooperatively annealing the metal substrate 2 and the mixed layer; and separating out the carbon material from the mixed layer to form the continuous graphene structure layer 11. By the abovementioned steps of this instant disclosure, the continuous graphene structure layer 11 having a large continuous area can be formed on the metal substrate 2 such as stainless steel or iron. Since the continuous graphene structure layer 11 is separated out from the metal substrate 2 directly, in other words, the continuous graphene structure layer 11 grows from the metal substrate 2, the graphene would be an entire continuum to form a continuous graphene structure layer 11. Thus, the continuous graphene structure layer 11 of this instant disclosure has tougher structure to provide superior buffering effect, and to increase anti-wear capability between the continuous graphene structure layer 11 and the metal substrate 2 and the coating layer 10, so as to further enhance load capacity of the coating layer 10 and elongate the lifetime of the coating layer 10.

In addition to the abovementioned method of forming the continuous graphene structure layer 11, in other embodiments, the method of forming the continuous graphene structure layer 11 of this instant disclosure also can be cooperated with an epitaxial growth method, a chemical vapor deposition (CVD) method, or a reduction from grapheme oxides method to form the continuous graphene structure layer 11.

In this instant disclosure, the machine element includes elements of a fluid machine, e.g., blower, air compressor, liquid compressor, vacuum pump or liquid pump. The metal substrate 2 of the embodiment in this instant disclosure is the abovementioned machine element material, stainless steel or iron. In the embodiment of this instant disclosure, the coating layer 10 is composed of polytetrafluoroethene (PTFE), but also can be composed of PTFE plus molybdenum disulfide (MoS₂), engineering plastics, and polymer materials. In addition, in the embodiment of this instant disclosure, the coating layer 10 is selected from a group consisting of polytetrafluoroethylene, polytetrafluoroethylene plus molybdenum disulfide, molybdenum disulfide, polyamide-imide resin, boron nitride, electroless nickel, tetrafluoroethylene-perfluoroalkyl (PFA), diamond-like carbon film (DLC), phosphate film, and combinations thereof. Preferably, the combinations of coating layer 10 are, polytetrafluoroethylene plus molybdenum disulfide, polyamide-imide resin plus molybdenum disulfide, boron nitride plus electroless nickel plus molybdenum disulfide, tetrafluoroethylene-perfluoroalkyl, phosphate film plus electroless nickel.

As shown in FIG. 3, another embodiment of this instant disclosure provides a coating layer structure 1 applied to a machine element which includes a continuous graphene structure layer 11 and a coating layer 10. The continuous graphene structure layer 11 is disposed on a metal substrate 2, and has a large continuous area structure. The coating layer 10 is disposed on the continuous graphene structure layer 11 for cooperatively protecting the metal substrate 2. The continuous graphene structure layer 11 is disposed between the metal substrate 2 and the coating layer 10 to act as a buffer structure between the metal substrate 2 and the coating layer 10.

Graphene is made of carbon atoms and has a mono layer sheet structure. The carbon atoms of graphene build up a flat film having a plurality of hexagonal honeycomb lattices by sp² hybrid orbitals, and a thickness of the flat film is identical with the thickness of a carbon atom. Graphene is well-known as the thinnest and most hard dimensional nano material, its thermal conductivity reaches up to 5300 W/m·K, and the thermal conductivity of graphene is even beyond the thermal conductivities of carbon nanotubes and diamond respectively. As the temperature increases, the thermal conductivity of graphene would decrease. When under extremely high temperature (near the adiabatic state), the graphene would not soften under ultrahigh temperature, but would be of increased strength. For example, when the temperature is higher than 2000° C., a tensile strength of graphene would be twice as strong as the tensile strength of graphene under room temperature. Furthermore, the thermal expansion coefficient of graphene is small, it is only 1.2×10⁻⁶/° C., such that the volume of graphene would not change much even if the temperature has a sudden change. Owing to the abovementioned characteristics of graphene, graphene has a superior load capability. In this way, when graphene is disposed between two materials, it can be a buffer structure between the two materials, so as to averagely disperse an applied pressure, and has heat dissipation effect.

There are a lot of methods for forming the continuous graphene structure layer 11 on the metal substrate 2, such as a spraying method, spin coating method, or forming the continuous graphene structure layer 11 first and then disposing the continuous graphene structure layer 11 between the coating layer 10 and the metal substrate 2. However, using the spraying method or the spin coating method to form the continuous graphene structure layer 11, since a graphene material must be dissolved in a solvent first for coating or spraying in liquid form, and the graphene material is difficult to disperse evenly in the solvent, this causes a graphene sheet structure to have uneven distribution in a graphene layer. At the same time, carbon-carbon bonds of graphene would be easily broken and appear as discontinuous structures, such that a substrate cannot be completely covered to raise a bearing load capability, or since not each of the graphene sheet structures in the graphene material keeps horizontally close to a contact surface of the metal substrate 2, and the graphene sheet structures in the graphene material contact to the contact surface of the metal substrate 2 in various contact angles that cause a contact area therebetween being decreased, so as to further reduce a bonding force between the graphene layer and the metal substrate 2. In addition, if the contact angle is larger, a positive force of the graphene layer becomes shear force to weaken its bearing load capability. If the continuous graphene structure layer 11 is formed first and then disposed between the coating layer 10 and the metal substrate 2, an adhesive material has to be spread or an adhesive layer has to be disposed between the continuous graphene structure layer 11 and the metal substrate 2 to stick the continuous graphene structure layer 11 and the metal substrate 2 together, but that complicates and increases the manufacturing cost. Simultaneously, if a coating structure without a graphene structure has a large continuous area, the coating layer structure 1 is easily peeled off due to the whole structure being unstable, and there is a risk of the metal material of the machine element being exposed to the air.

Via the manufacturing method of a coating layer structure 1 applied to the machine element of this instant disclosure, the mixed layer containing the carbon material and the metal material such as nickel or nickel alloy is deposited on the metal substrate 2, the metal substrate 2 and the mixed layer deposited on the metal substrate 2 are cooperatively conducted in an annealing treatment, and the continuous graphene structure layer 11 is separated out from the metal substrate 2 and grows on the metal substrate 2. The continuous graphene structure layer 11 has a large continuous area structure to contact with the metal substrate 2 and the coating layer 10 in a maximum contact area, so as to have a robust structure. In this way, the coating layer structure 1 of the embodiment of this instant disclosure has superior load capability to withstand stronger pressure, and the coating layer structure 1 is still firmly located on the metal substrate 2 of the fluid machine, so as to protect the fluid machine to not suffer from wear or corrosion.

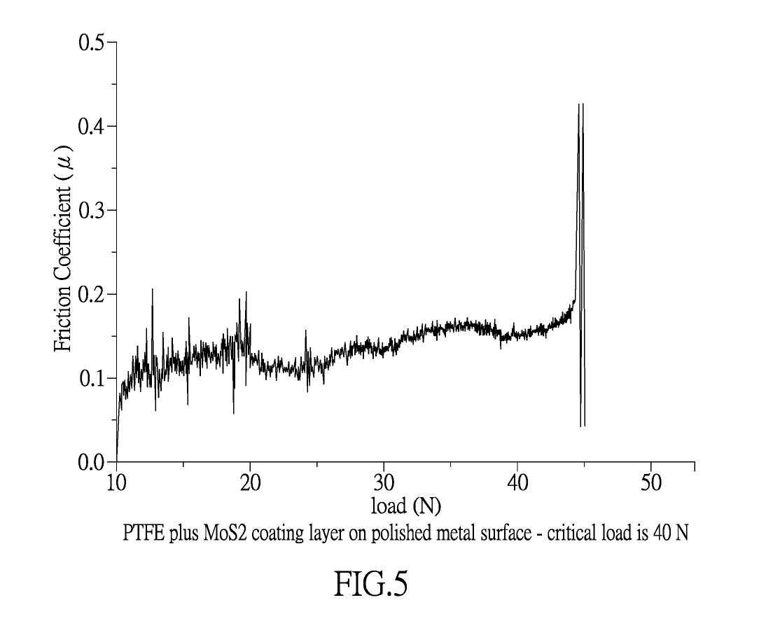

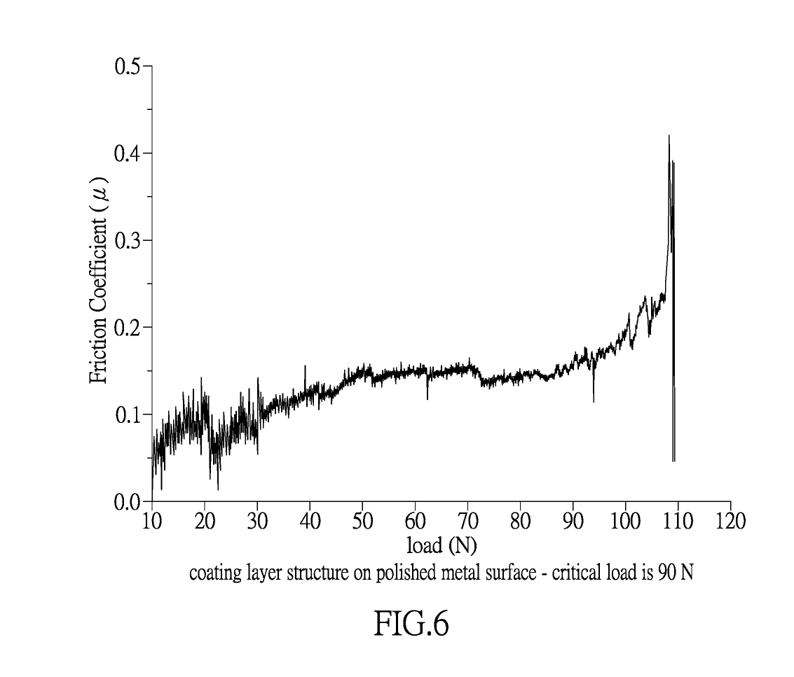

Please refer to FIGS. 4 to 6. FIG. 4 shows a critical load test result of a coating layer formed from polytetrafluoroethylene, FIG. 5 shows a critical load test result of a coating layer composed of polytetrafluoroethylene and molybdenum disulfide, and FIG. 6 shows a critical load test result of a coating layer structure applied to a machine element of an embodiment in this instant disclosure.

A critical load means a maximum load that a load layer can endure. The test is conducted such that a round pin is used to carry out a rotary abrasion test, the pin applies a test material with a steady load, and the applied load will be increased along within a certain time. For example, 10 Newton forces (N) is added on the pin to apply on the coating layer every 5 minutes, when the coating layer is unable to load, it will cause the coating layer to be peeled off. Since contact of the pin and the substrate results in a friction coefficient rising sharply, when the applied load brings about the coating layer being peeled off, at this time, the load is called critical load. In the embodiment of this instant disclosure, the critical load is associated with the anti-wear capability and the strength of coating layer between the coating layer structure 1 and the metal substrate 2. If the anti-wear capability and the strength of the coating layer are stronger, the load force of the coating layer structure 1 is larger, and the coating layer 10 is not easily peeled off.

As shown in FIG. 4, only PTFE was coated on a polished metal surface, when 20 N was applied thereon, the friction coefficient rose sharply after a few minutes, which represents that the PTFE coating layer started to peel off from the polished metal surface, thus the critical load is 20 N. As shown in FIG. 5, PTFE and MoS₂ were coated on the polished metal surface, when 40 N was applied thereon, the friction coefficient rose sharply after few minutes, which represents that the PTFE plus MoS₂ coating layer started to peel off from the polished metal surface, thus the critical load is 40 N. After adding MoS₂, the critical load of loading layer is increased. Then, as shown in FIG. 6, the coating layer structure 1 of this instant disclosure was formed on the polished metal surface, and when 90 N was applied thereon, the coating layer structure 1 started to peel off from the polished metal surface, thus the critical load is 90 N. Compared to the prior art groups (only PTFE coating layer and PTFE plus MoS₂ coating layer), the critical load of the coating layer structure 1 of this instant disclosure increases to more than twice that of the prior art groups. That is, the anti-wear capability between the coating layer structure 1 and the metal substrate 2 of this instant disclosure is two times stronger, the load capacity also rises beyond two times, and the coating layer structure 1 is not easily peeled off and is able to continuously protect the fluid machine, so as to lengthen the lifetime of the coating layer structure 1, coating layer 10, and fluid machine.

In summary, this instant disclosure has advantages in that, in a coating layer structure applied to a machine element and manufacturing method thereof provided from an embodiment of this instant disclosure, since the continuous graphene structure layer having a large continuous area structure is formed between the metal substrate of machine element and the coating layer, there is a maximum contact area between the continuous graphene structure layer and the coating layer and the metal substrate, and the coating layer structure becomes tougher, so as to further improve the anti-wear capability between the continuous graphene structure layer and the metal substrate and the coating layer. In addition, since the continuous graphene structure layer formed between the metal substrate and the coating layer of the fluid machine can be used as a buffer structure between the metal substrate and the coating layer, the load capacity of the coating layer is enhanced, such that the coating layer is not easily peeled off and the lifetime of the coating layer can be lengthened, Therefore, the coating layer structure of this instant disclosure can protect the metal substrate of the machine element to avoid any suffering of mechanical wear or corrosion caused by wetness, so as to further lengthen the lifetime of the machine element.

The descriptions illustrated supra set forth simply the preferred embodiments of the instant disclosure; however, the characteristics of the instant disclosure are by no means restricted thereto. All changes, alterations, or modifications conveniently considered by those skilled in the art are deemed to be encompassed within the scope of the instant disclosure delineated by the following claims.

What is claimed is:

1. A manufacturing method of a coating layer structure applied to a machine element, comprising:
forming a continuous graphene structure layer on a metal substrate; and
forming a coating layer on the continuous graphene structure layer for cooperatively protecting the metal substrate;
wherein the continuous graphene structure layer is disposed between the metal substrate and the coating layer to act as a buffer structure between the metal substrate and the coating layer.

2. The manufacturing method of a coating layer structure applied to a machine element as claimed in claim 1, wherein steps of forming the continuous graphene structure layer on the metal substrate comprise:
depositing a mixed layer containing a carbon material and a metal material on the metal substrate;
cooperatively annealing the metal substrate and the mixed layer; and
separating out the carbon material from the mixed layer to form the continuous graphene structure layer.

3. The manufacturing method of a coating layer structure applied to a machine element as claimed in claim 2, wherein a sputtering method or a vapor deposition method is used in the step of depositing the mixed layer on the metal substrate.

4. The manufacturing method of a coating layer structure applied to a machine element as claimed in claim 2, wherein the metal material in the mixed layer is nickel or nickel alloy.

5. The manufacturing method of a coating layer structure applied to a machine element as claimed in claim 1, wherein the metal substrate is stainless steel or iron.

6. The manufacturing method of a coating layer structure applied to a machine element as claimed in claim 1, wherein the coating layer is selected from a group consisting of polytetrafluoroethylene, polytetrafluoroethylene plus molybdenum disulfide, molybdenum disulfide, polyamide-imide resin, boron nitride, electroless nickel, tetrafluoroethylene-perfluoroalkyl, diamond-like carbon film, phosphate film, and combinations thereof.

7. The manufacturing method of a coating layer structure applied to a machine element as claimed in claim 1, wherein the coating layer is composed of polytetrafluoroethylene and molybdenum disulfide.

8. A coating layer structure applied to a machine element, comprising:
a continuous graphene structure layer disposed on a metal substrate; and
a coating layer disposed on the continuous graphene structure layer for cooperatively protecting the metal substrate;
wherein the continuous graphene structure layer is disposed between the metal substrate and the coating layer to act as a buffer structure between the metal substrate and the coating layer.

9. The coating layer structure applied to a machine element as claimed in claim 8, wherein the metal substrate is stainless steel or iron.

10. The coating layer structure applied to a machine element as claimed in claim 8, wherein the coating layer is selected from a group consisting of polytetrafluoroethylene, polytetrafluoroethylene plus molybdenum disulfide, molybdenum disulfide, polyamide-imide resin, boron nitride, electroless nickel, tetrafluoroethylene-perfluoroalkyl, diamond-like carbon film, phosphate film, and combinations thereof.

11. The coating layer structure applied to a machine element as claimed in claim 8, wherein the coating layer is composed of polytetrafluoroethylene and molybdenum disulfide.
